(19) United States
(12) Patent Application Publication
(10) Pub. No.: US 2009/0175115 A1
(43) Pub. Date: Jul. 9, 2009

(54) MEMORY DEVICE, METHOD FOR ACCESSING A MEMORY DEVICE AND METHOD FOR ITS MANUFACTURING

(76) Inventors: Christoph Bilger, Munich (DE); Peter Gregorius, Munich (DE); Michael Bruennert, Munich (DE); Maurizio Skerlj, Munich (DE); Wolfgang Walthes, Munich (DE); Johannes Stecker, Munich (DE); Hermann Ruckerbauer, Moos (DE); Dirk Scheideler, Munich (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/971,880

(22) Filed: Jan. 9, 2008

(51) Int. Cl. G11C 8/18

(52) U.S. Cl. 365/233.5

(57) ABSTRACT

Embodiments relates to a memory device, comprising a plurality of memory cells, said memory cells being addressable by a plurality of addresses, an interface for reading and/or writing data from a host system to said memory device, said interface comprising at least an address bus and a clock signal line, said address bus being configured to transmit a first part of an address at the leading edge of said clock signal and a second part of an address at the trailing edge of said clock signal.

### BACKGROUND OF THE INVENTION

The invention relates to the field of semiconductor memory devices, e.g. DRAM-devices, SRAM-devices or Flash-EEPROM-devices. In particular, the invention relates to a protocol for transmitting an address related to one or more memory cells from a host system to a memory device.

A memory device comprises a plurality of memory cells and may comprise some integrated circuits to perform some basic functions of the memory device such as mapping addresses to memory cells, hiding defective memory cells from further use or the like. The memory device may be assembled on a printed circuit board or integrated on a single semiconductor die.

Memory devices are commonly used in electronic systems incorporating digital electronics, such as personal computers, music players, digital cameras, networking servers, routers or the like. An electronic system comprising said memory device is hereinafter referred to as host system. The memory device may be inserted into the host system as a separate module or may be integrated on the same printed circuit board. Usually, the host system comprises a microprocessor to perform its basic tasks. Furthermore, the host system comprises a memory control unit, either integrated into the microprocessor, integrated into the memory device or as a stand-alone device. The memory control unit is configured to establish and control an interface between at least one memory device and the host system. To perform read and write operations on the memory device, the memory control unit specifies the address of at least one memory cell and transmits this address to the memory device. The host system and the memory device are synchronized by a common clock signal. The memory device itself or at least parts of the memory device may or may not operate at a higher clock cycle. These higher or lower clock cycles are generated from the main clock cycle. Therefore, all clock frequencies are synchronized to each other.

### BRIEF DESCRIPTION OF THE DRAWINGS

For a more complete understanding of the present invention and the advantages thereof, reference is made to the following description taken in conjunction with the accompanying drawings in which:

FIG. 1 shows a timing diagram of a memory device according to one embodiment of the present invention.

FIG. 2 shows a schematic diagram of a memory device according to one embodiment of the present invention.

### DETAILED DESCRIPTION OF THE PREFERRED EMBODIMENT

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, in various embodiments the invention provides numerous advantages over the prior art. However, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Also, signal names used below are exemplary names, indicative of signals used to perform various functions in a given memory device. In some cases, the relative signals may vary from device to device. Furthermore, the circuits and devices described below and depicted in the figures are merely exemplary of embodiments of the invention. As recognized by those of ordinary skill in the art, embodiments of the invention may be utilized with any memory device.

Embodiments of the invention may generally be used with any type of memory. In one embodiment, the memory may be a circuit included on a device with other types of circuits. For example, the memory may be integrated into a processor device, memory controller device, or other type of integrated circuit device. Devices into which the memory is integrated may include system-on-a-chip (SOC) devices. In another embodiment, the memory may be provided as a memory device which is used with a separate memory controller device or processor device.

In both situations, where the memory is integrated into a device with other circuits and where the memory is provided as a separate device, the memory may be used as part of a larger computer system. The computer system may include a motherboard, central processor, memory controller, the memory, a hard drive, graphics processor, peripherals, and any other devices which may be found in a computer system. The computer system may be part of a personal computer, a server computer, or a smaller system such as an embedded system, personal digital assistant (PDA), or mobile phone.

In some cases, a device including the memory may be packaged together with other devices. Such packages may include any other types of devices, including other devices with the same type of memory, other devices with different types of memory, and/or other devices including processors and/or memory controllers. Also, in some cases, the memory may be included in a device mounted on a memory module. The memory module may include other devices including memories, a buffer chip device, and/or a controller chip device. The memory module may also be included in a larger system such as the systems described above.

In some cases, embodiments of the invention may be used with multiple types of memory or with a memory which is included on a device with multiple other types of memory. The memory types may include volatile memory and non-volatile memory. Volatile memories may include static random access memory (SRAM), pseudo-static random access memory (PSRAM), and dynamic random access memory (DRAM). DRAM types may include single data rate (SDR) DRAM, double data rate (DDR) DRAM, low power (LP) DDR DRAM, and any other types of DRAM. Nonvolatile memory types may include magnetic RAM (MRAM), flash memory, resistive RAM (RRAM), ferroelectric RAM (FeRAM), phase-change RAM (PRAM), electrically erasable programmable read-only memory (EEPROM), laser programmable fuses, electrically programmable fuses (e-fuses), and any other types of nonvolatile memory.

Embodiments provided herein generally provide for transmitting addresses. One embodiment of the invention relates to a memory device comprising a plurality of memory cells. Said memory cells are addressable by a plurality of addresses. The memory device according to this embodiment further comprises an interface for reading and/or writing data from a host system to said memory device, said interface comprising at least an address bus and a clock signal line. The address bus is configured to transmit a first part of an address at the leading edge of said clock signal and a second part of an address at the trailing edge of said clock signal.

Another embodiment of the invention relates to a memory device comprising a plurality of memory cells. The memory cells are at least logically arranged in columns and rows. Furthermore, the memory device comprises an interface for reading and/or writing data from a host system to the memory device. The interface comprises at least an address bus and a clock signal line, wherein said address bus is configured to transmit a first part of an address representing a row at the leading edge of said clock signal and a second part of an address representing a column at the trailing edge of said clock signal.

Another embodiment of the invention relates to a method for accessing a memory device comprising a plurality of memory cells, wherein said memory cells are addressable by a plurality of addresses. The method according to this embodiment comprises the step of providing an address bus and a clock signal. A first part of an address is transmitted from the host system to the memory device at the leading edge of said clock signal and a second part of an address is transmitted at the trailing edge of said clock signal. After the address has been transmitted, the data can be read or written to the respective memory cells of the memory device.

Another embodiment of the invention relates to a method for accessing a memory device comprising a plurality of memory cells which are arranged in columns and rows. A single memory cell is addressable by its specific column and row. The method according to this embodiment comprises the step of providing an address bus and a clock signal between said memory device and the host system comprising said memory device. A first part of an address representing a row is transmitted at the leading edge of said clock signal and a second part of an address representing a column is transmitted at the trailing edge of said clock signal. After the address has been transmitted, data are read or written from the specified memory cells.

In still another embodiment, the invention relates to a method for manufacturing a memory device comprising the following steps: providing a plurality of memory cells, said memory cells being addressable by a plurality of addresses. Providing an interface for reading and/or writing data from a host system to said memory device, said interface comprising at least an address bus and a clock signal line, wherein said address bus is configured to transmit a first part of an address at the leading edge of said clock signal and a second part of an address at a trailing edge of said clock signal.

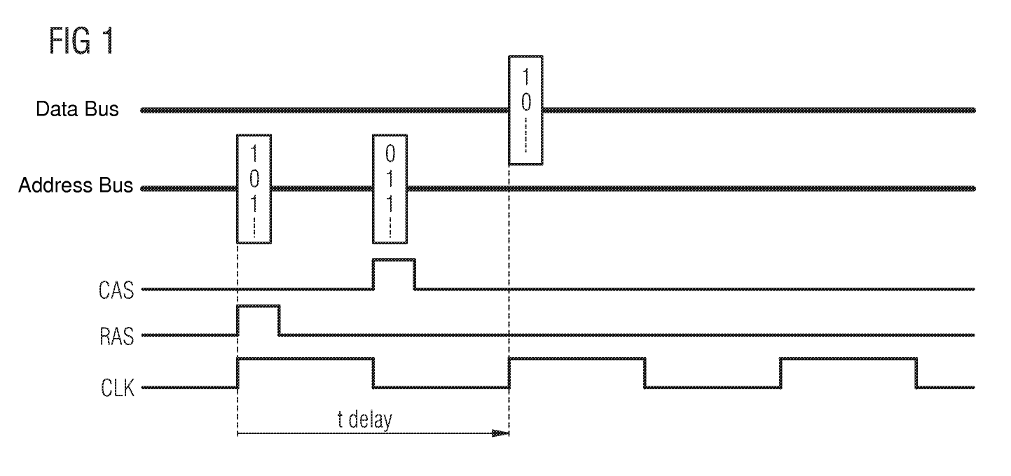

Reference is now made to FIG. 1 which shows a timing diagram taken at the interface between a host system and a memory device according to one embodiment of the present invention. The first line shows a signal which can be measured on a data bus between the host system and a memory device. The data bus comprises physically at least one line which is configured to transmit data between the memory device and the host system comprising the memory device. The data bus may comprise physically more than one line to transmit a plurality of data bits at the same time. As an example, the data bus may comprise 16, 32, 64 or 128 parallel lines. Nevertheless, the invention is not limited to this number of data lines. Each data line may be made from a conductor to transmit data in the form of an electric pulse. In this case, a further conductor to transmit a reference or ground potential may be provided. The reference potential may be provided by a single line for all respective data lines or by a plurality of reference lines. In another embodiment of the invention, the data bus may comprise a wireless data transmission or an optical data transmission path.

The second line in FIG. 1 represents the signal which can be measured on an address bus. The address bus itself comprises at least one digital line to transmit address data from a host system to the memory device. The address bus may comprise a plurality of lines to transmit a plurality of bits at the same time. As an example, the address bus may comprise ten parallel lines. As the data bus, the address bus may be realized as a conductor, a wireless communication or an optical communication.

The third line indicated in FIG. 1 represents the signal on a CAS-line. The CAS is a single digital line indicating that the currently transmitted address data concerns a column number.

The fourth line represents the signal on the RAS-line. The RAS is transmitted via a single digital line and indicates that the address data transmitted on the address bus is a row address.

The fifth signal indicated in FIG. 1 is a clock signal. Usually, the clock signal is generated by the host system. Nevertheless, the clock signal may be generated at any other location including the memory device. The clock signal is used to synchronize the communication between the host system and the memory device. As an example, the clock signal may feature a period from one pulse every 16 ns up to one pulse every 2 ns.

Furthermore, the clock signal is used to synchronize any internal circuitry of the memory device with respect to each other and with the host system. In order to achieve this task, any internal circuitry of the memory device operates either at the clock signal as detailed in FIG. 1 or at an internal clock signal comprising a fraction or a multiple of the frequency of the external clock signal.

Apart from the five signals detailed in FIG. 1, the interface between the host signal and the memory device may comprise further lines to transmit further signals, e.g. a command bus. Embodiments of the present invention are not limited to the number of interconnections to the number detailed in FIG. 1.

The memory device itself comprises a plurality of memory cells. The memory cells may be arranged in columns and rows so that each single memory cell can be identified by indicating their respective column and row address. Of course, the invention is not limited to this example. The invention can be applied to any memory device comprising memory cells with an address in a two part form. Apart from a column and a row, said two parts of an address may represent a radius and an angle or a number and a depth as well as any other example. Also the address may consist in more than two parts such as 3 parts or 4 parts.

Every read or write command is preceded by address data which indicate the respective memory cells into which data are to be written or from which data are to be read. After the respective address data and the command has been sent, the data are transferred between the host system and the memory device.

FIG. 1 indicates the state of different lines at the interface between the host and the memory system at different times. The time proceeds from left to right. As an example, a read operation is explained. It should be clear from the following explanation that a write operation is executed in the same manner.

At the beginning, triggered by the leading edge of a clock signal, first data representing a first part of an address are sent from the host system to the memory device via the address bus. As the CAS-line is low and the RAS-line is high, the memory device is instructed that the address data represent a row address. The first part of the address is received by a receiving unit located on the memory device and transmitted to a row decoding unit.

At the falling edge of the same clock cycle, a second data representing a second part of an address is sent from the host system via the address bus to the memory device. At this moment, the RAS-line becomes low and the CAS-line becomes high, indicating that the data received by the memory device is a column address. The second part of the address is received by a receiving unit on the memory device and handed over to a column decoding unit.

In the example of FIG. 1, the full address has been transmitted in one clock cycle. If an address is transferred by more than two parts, further clock cycles to transmit the remaining parts may follow.

Referring to FIG. 1, the full address has been received at the end of the first clock cycle. The respective read command can be executed immediately after this clock cycle. After execution of the command, the data from the respective memory cells is sent by means of the data bus as soon as possible. The point in time at which the data are sent is limited only by internal delays. The point in time may be given by the leading edge of the next clock cycle.

It is understood that the leading edge of a clock cycle is not necessarily a rising edge. Depending on the system used, the leading edge of a clock cycle may be a rising or a falling edge. The trailing edge of said clock cycle is then a falling or a rising edge respectively. According to the invention, a plurality of address information can be transmitted within one clock cycle without the need of doubling the number of external connection pins.

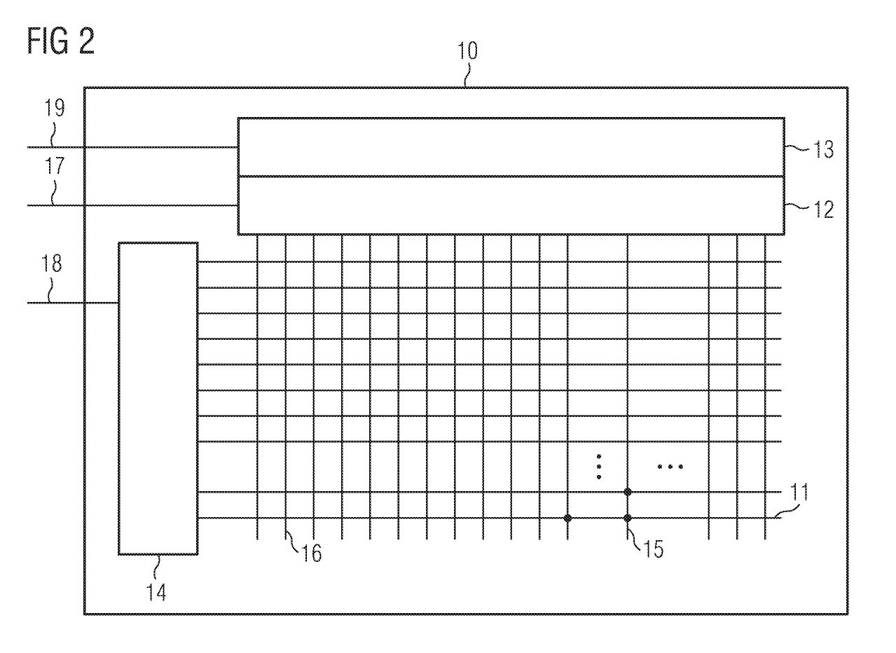

FIG. 2 shows one exemplary embodiment of a memory device 10. The memory device 10 consists in a plurality of word lines 11 and a plurality of data lines 16. FIG. 2 shows ten word lines 11 and sixteen data lines 16. However, the number of word lines and data lines is not limited to these numbers.

Furthermore, the memory device comprises a plurality of storage cells 15. Some of these storage cells are indicated in FIG. 2 as filled circles. Each storage cell is connected to a data line and a word line. This results in the word lines and the data lines forming a grid. However, the invention is not limited to configurations wherein the storage cells form a rectangular grid. The storage cells may be of, for example, DRAM-, SRAM- or EEPROM-type or the like. Embodiments of the invention are not limited to the use of a specific type of storage cells.

Each word line is connected to a row decoder 14. The row decoder receives a row address from the host system by an address line 18. The address line 18 may consist in physically more than one line to allow sending a plurality of address bits at the same time to the row decoder 14. The address line 18 is generally representative of an interconnection between the host system and the row decoder 14 which may include one or more other devices such as a receiver, a sender or a buffer.

The plurality of data lines 16 are connected to a plurality of sense amplifiers 12 and a column decoder 13. The sense amplifier 12 is configured to detect an amount of electrical charge stored in a storage cell 15. According to the amount of charge stored in the storage cell 15, a logical value is assigned to the respective storage cell.

In operation of the memory device storage cells 15 to be read or to be written are selected by column decoder 13. The column decoder 13 receives an address information from the host system on address line 19. The address line 19 may consist of physically more than one line. The connection from the host system to the column decoder 13 may comprise one or more devices such as a receiver, a sender or a buffer. After storage cells have been selected by sending addresses to row decoder 14 and column decoder 13 and the respective data lines 16 and word lines 11 have been activated, the respective data is read out by data lines 17. Again, it has to be noted that data lines 17 may consist of physically more than one interconnecting line.

Although several embodiments of the invention have been illustrated in the accompanying drawings and described in the foregoing detailed description, it will be understood that the invention is not limited to the embodiments disclosed, but is capable of numerous rearrangements, modifications and substitutions without departing from the scope of the invention. The invention has been described in the form of functional elements such as a memory control unit, a column decoder 13, a row decoder 14 or a plurality of storage cells 15. Those elements are known to those skilled in the art and may be realized in different embodiments. The invention does not rely on the strict realization of a certain embodiment.

What is claimed is:

1. A memory device, comprising:
a plurality of memory cells, said memory cells being addressable by a plurality of addresses;
an interface for reading and/or writing data from a host system to said memory device;
said interface comprising at least an address bus and a clock signal line; and
said address bus being configured to transmit a first part of an address at the leading edge of a clock signal transmitted over the clock signal line and a second part of an address at the trailing edge of said clock signal in one clock cycle.

2. The memory device according to claim 1, wherein said memory cells are arranged in columns and rows.

3. The memory device according to claim 2, wherein said first part of an address represents a column address and said second part of an address represents a row address.

4. The memory device according to claim 2, wherein said first part of an address represents a row address and said second part of an address represents a column address.

5. The memory device according to claim 1, wherein said memory cells comprise dynamic random access memory cells.

6. The memory device according to claim 1, wherein said memory device is a synchronous memory device.

7. The memory device according to claim 1, further comprising a command bus, said command bus being configured to transmit a command related to said first part of an address at the leading edge of said clock signal and a command related to said second part of an address at the trailing edge of said clock signal.

8. A memory device, comprising:
a plurality of memory cells, said memory cells being arranged in columns and rows;
an interface for reading and/or writing data from a host system to said memory device;
said interface comprising at least an address bus and a clock signal line; and
said address bus being configured to transmit a first part of an address representing a row at the leading edge of said clock signal and a second part of an address representing a column at the trailing edge of said clock signal in one clock cycle.

9. The memory device according to claim 8, wherein said memory cells comprise dynamic random access memory cells.

10. The memory device according to claim 8, wherein said memory device is a synchronous memory device.

11. The memory device according to claim 8, further comprising a command bus, said command bus being configured to transmit a command related to said first part of an address at the leading edge of said clock signal and a command related to said second part of an address at the trailing edge of said clock signal.

12. A method for accessing a memory device comprising a plurality of memory cells, said memory cells being addressable by a plurality of addresses, said method comprising:
providing an address bus and a clock signal;
transmitting a first part of an address over the address bus at the leading edge of said clock signal;
transmitting a second part of an address at the trailing edge of said clock signal over the address bus, wherein the leading edge and the trailing edge of said clock signal occur in one clock cycle; and
accessing the memory cells at the transmitted addresses; wherein accessing comprises one of reading data from the memory cells at the transmitted addresses and writing data to the memory cells comprising the transmitted addresses.

13. The method according to claim 12, wherein said memory cells are arranged in columns and rows and said first part of an address represents a column address and said second part of an address represents a row address.

14. The method according to claim 12, wherein said memory cells are arranged in columns and rows and said first part of an address represents a row address and said second part of an address represents a column address.

15. The method according to claim 12, wherein said memory cells comprise dynamic random access memory cells.

16. The method according to claim 12, wherein said memory device is a synchronous memory device.

17. The method according to claim 12, wherein said address bus is provided between said memory device and a host system comprising said memory device.

18. The method according to claim 12, wherein a command bus is provided and a command related to said first part of an address is transmitted at the leading edge of said clock signal and a command related to said second part of an address is transmitted at the trailing edge of said clock signal.

19. A method for accessing a memory device comprising a plurality of memory cells, said memory cells being arranged in columns and rows and being addressable by a plurality of addresses, said method comprising:
providing an address bus and a clock signal line between said memory device and a host system comprising said memory device;
transmitting a first part of an address representing a row address at a leading edge of a clock signal transmitted over the clock signal line;
transmitting a second part of the address representing a column address at the trailing edge of said clock signal; and
accessing the memory cells at the transmitted address; wherein accessing comprises one of reading data from the memory cells located at the transmitted address and writing data to the memory cells located at the transmitted address.

20. The method according to claim 19, wherein said memory device is a synchronous memory device.

21. The method according to claim 19, wherein said memory cells comprise dynamic random access memory cells.

22. The method according to claim 19, wherein a command bus is provided and a command related to said first part of an address is transmitted at the leading edge of said clock signal and a command related to said second part of an address is transmitted at the trailing edge of said clock signal.

23. A method for manufacturing a memory device, comprising:
providing a plurality of memory cells, said memory cells being addressable by a plurality of addresses; and
providing an interface for reading and/or writing data from a host system to said memory device, said interface comprising at least an address bus and a clock signal line, said address bus being configured to transmit a first part of an address at the leading edge of said clock signal and a second part of the address at the trailing edge of said clock signal, wherein the leading edge and the trailing edge of said clock signal occur in one clock cycle.

24. The method according to claim 23, wherein said memory cells are arranged in columns and rows.

25. The method according to claim 23, wherein said memory cells comprise dynamic random access memory cells.

26. The memory device according to claim 1, further comprising:
a row address strobe (RAS) line for transmitting a RAS which assumes an active level when the first part of the address is present on the address bus; and
a column address strobe (CAS) line for transmitting a CAS which assumes an active level when the second part of the address is present on the address bus.
